(19) United States
(12) Patent Application Publication
(10) Pub. No.: US 2005/0068438 A1
(43) Pub. Date: Mar. 31, 2005

(54) Low noise CMOS amplifier for imaging sensors

(75) Inventor: Lester J. Kozlowski, Simi Valley, CA (US)

Correspondence Address: Doyle B. Johnson;REED SMITH CROSBY HEAFEY LLP, Suite 2000, Two Embarcadero Center, San Francisco, CA, 94111, US

(73) Assignee: Innovative Technology Licensing, LLC

(21) Appl. No.: 10/675,854

(22) Filed: Sep. 30, 2003

(51) Int. Cl. H04N 3/14; H04N 5/335; H01L 27/00

(52) U.S. Cl. 348/308; 348/301; 250/208.1

(57) ABSTRACT

A CMOS pixel amplifier circuit includes four transistors having the same polarity, and a photodetector. An access supply connects to the pixel circuit via a bus and is configured as a current source that acts as a distributed feedback amplifier, when it is connected to the pixel transistors. The access supply connects to an access MOSFET that isolates a common node from an output node. In this configuration, the feedback amplifier is a cascoded inverter, which provides gains 100-1000 times greater than prior circuits.

### BACKGROUND OF THE INVENTION

1. Field of the Invention

The present invention relates generally to CMOS imaging devices, and more particularly to a low noise amplifier for use with high performance image sensors.

2. Description of the Related Art

Visible imaging systems implemented in CMOS have the potential for significant reductions in cost and power requirements in components such as image sensors, drive electronics, and output signal conditioning electronics. A video camera, for example, can be configured as a single CMOS integrated circuit supported by only an oscillator and a battery. Such a CMOS imaging system requires lower voltages and dissipates less power than a CCD-based system. These improvements translate into smaller camera size, longer battery life, and applicability to many new products.

Because of the advantages offered by CMOS visible imagers, there has been considerable effort to develop active-pixel sensor (APS) devices. Active-pixel sensors can provide low read noise comparable or superior to scientific grade CCD systems. The active circuit in each pixel of an APS device, however, utilizes cell “real estate” that could otherwise be used to enable imagers having optical format compatible with standard lenses and/or to maximize the sensor optical fill factor for high sensitivity. Active-pixel circuits also may increase power dissipation relative to passive-pixel alternatives, increase fixed pattern noise (possibly requiring additional circuitry to suppress the noise), and limit scalability.

U.S. Pat. No. 6,456,326, entitled SINGLE CHIP CAMERA DEVICE HAVING DOUBLE SAMPLING OPERATION, inventors Fossum et al., teaches pixel-based means to suppress pixel-generated noise via conventional correlated double sampling. However, this invention neither addresses scalability nor compatibility with foundry processes since floating gates transparent to all wavelengths of interest are not generally available. Furthermore, the sampling node is vulnerable to discharge due to stray light.

U.S. Pat. No. 6,566,697, entitled PINNED PHOTODIODE FIVE TRANSISTOR PIXEL, inventors Fox et al. is compatible with production at standard CMOS processes, but is not directly scalable since it comprises five transistors. Further, the high impedance node 18 generates reset noise and is vulnerable to pickup of feed-through offsets that create fixed pattern noise.

As disclosed in U.S. Pat. No. 6,493,030, entitled LOW-NOISE ACTIVE PIXEL SENSOR FOR IMAGING ARRAYS WITH GLOBAL RESET, inventors Kozlowski et al., herein incorporated by reference, a scalable high-performance low-noise amplifier system for a CMOS image sensor that can be produced in standard CMOS process technology may be formed as shown in FIG. 1. Each pixel 10 in a sensor array (not shown) comprises a photodetector 12, such as a photodiode, for example, connected to the gate of a dual-driver MOSFET 14, and one leg of a reset MOSFET 16. The other leg of MOSFET 16 is connected to a leg of MOSFET 14 and a leg of MOSFET 20. MOSFET 20 acts as a current source during global reset and as a switch during pixel readout. A row select MOSFET 18 has one leg connected to MOSFET 14 and the other leg connected to column bus 24. Column bus 24 connects all the pixels in a column of the photodetector array by way of the row select MOSFET 18 to a source supply 30. Row bus 22 connects all the pixel resets in a row to an access supply V_{dd}. Tapered reset supply 50 supplies an optimized active-pixel reset waveform, as disclosed in the U.S. Pat. No. 6,493,030 patent and illustrated in FIG. 2, to the gate of MOSFET 16.

Reset is initiated by fully enabling the row select MOSFETs 18 of the pixels in the selected row, thereby connecting a low-impedance voltage source (located in source supply 30) to one leg of MOSFET 14 for all the pixels in the row. An embodiment of the source supply 30 is shown in FIG. 3 of the patent. Dual purpose MOSFET 20 is biased as a current source by waveform V_{bias} on gate 26 so that all the pixel amplifiers in the imager are configured as transimpedance amplifiers with capacitive feedback provided by MOSFET'S 14 Miller capacitance. MOSFET 14 thus acts as a transconductance, and reset MOSFET 16 acts as a resistance controlled by the tapered reset supply 50. The series resistance of MOSFET 16 is gradually increased by applying a decreasing ramp waveform to the gate of MOSFET 16 to give the feedback transconductance of MOSFET 14 the opportunity to null the reset noise (kTC).

As described, MOSFET 20 is configured as a P-FET (see FIGS. 5 and 6 of the U.S. Pat. No. 6,493,030 patent), whereas the other transistors are N-FETs. In such a configuration, the distributed feedback amplifier is a simple inverter, and provides the gain necessary to facilitate the tapered reset noise suppression mechanism to suppress the reset noise. It would be desirable, however, to have an amplifier configured to provide more gain than is provided by a simple inverter circuit.

### SUMMARY OF THE INVENTION

In general, the present invention is an active pixel sensor circuit having a feedback amplifier configured as a cascoded inverter, which provides increased amplifier gain, while still providing low noise amplification.

Specifically, in one embodiment, the present circuit comprises four transistors having the same polarity, and a photodetector for each pixel. The present circuit is compact and compatible with pixel pitch below 3 μm using 0.18 μm CMOS fabrication technology. Being a distributed inverter amplifier wherein amplifier components are located both within the pixel and outside of the pixel, the present circuit is compact and compatible with pixel pitch below 3 μm using 0.18 μm CMOS fabrication technology. An access supply connected to the active pixel circuit is a current source that acts as a distributed feedback amplifier, when it is connected to the pixel transistors. The access supply connects to an access MOSFET that isolates a common node from an output node. In this configuration, the feedback amplifier is a cascoded inverter, which provides gains 100-1000 times greater than the circuit illustrated in FIG. 1.

### BRIEF DESCRIPTION OF THE DRAWINGS

The present invention will be readily understood by the following detailed description in conjunction with the accompanying drawings, wherein like reference numerals designate like structural elements, and in which:

FIG. 1 is a block diagram of a prior art circuit;

FIG. 2 is a signal diagram showing a representative clocking for a tapered-reset waveform for use with the present invention;

FIG. 3 is a schematic circuit diagram illustrating an embodiment of a column-based source supply circuit for use with the present invention;

FIG. 4 is a block diagram of an embodiment of the present invention; and

FIG. 5 is a diagram of an embodiment of the access supply according to the present invention.

### DETAILED DESCRIPTION OF THE INVENTION

The following description is provided to enable any person skilled in the art to make and use the invention and sets forth the best modes contemplated by the inventor for carrying out the invention. Various modifications, however, will remain readily apparent to those skilled in the art, since the basic principles of the present invention have been defined herein specifically to provide a low noise amplifier for CMOS image sensors. Any and all such modifications, equivalents and alternatives are intended to fall within the spirit and scope of the present invention.

The present invention has the advantages of full process compatibility with standard salicided (self-aligned silicide) submicron CMOS. This helps maximize yield and minimize die cost because the circuit complexity is distributed amongst the active-pixels and peripheral circuits, and exploits signal-processing capability inherent to CMOS. The invention's spectral response is broad from the near-ultraviolet (400 nm) to the near-IR (>950 nm).

Because the low-noise system of the present invention has only four MOSFETs in each pixel, the invention offers as-drawn optical fill factor >40% at 5 μm pixel pitch using 0.25 μm design rules in CMOS. The actual optical fill factor is somewhat larger due to lateral collection and the large diffusion length of commercial CMOS processes. A final advantage is the flexibility to collocate digital logic and signal-processing circuits due to its high immunity to electromagnetic interference.

When fully implemented in a desired camera-on-a-chip architecture, the low-noise active pixel sensor (APS) can provide temporal read noise below 5 e- (at data rates compatible with either video imaging or still photography via electronic means), fixed pattern noise significantly below 0.02% of the maximum signal (on a par with competing CCD imagers), <0.5% non-linearity, ≧1 V signal swing for 3.3 V power supply, large charge-handling capacity, and variable sensitivity using simple serial interface updated on a frame-by-frame basis via digital interface to a host microprocessor.

A prototype embodiment of the low-noise APS invention formed a visible imager comprising an array of 1920 (columns) by 1080 (rows) of visible light detectors (photodetectors). The rows and columns of pixels were spaced 5 microns center-to-center using standard 0.25 μm design rules to provide 50% as-drawn optical fill factor. Subsequent layouts using 0.18 μm rules show that the invention can also provide similar fill factor at 4 μm pitch. Several columns and rows of detectors at the perimeter of the light-sensitive region were covered with metal and used to establish the dark level for off-chip signal processing. In addition, the detectors in each row were covered with color filters to produce color imagers. For example, the odd rows may begin at the left with red, green, then blue filters, and the even rows may begin with blue, red, then green filters, with these patterns repeating to fill the respective rows.

A low-noise active-pixel sensor 100 according to the present invention is illustrated in FIG. 4. Each pixel 100 in a sensor array (not shown) comprises a photodetector 120, such as a photodiode, for example, connected to the gate of a dual-driver MOSFET 140, and one leg of a reset MOSFET 160. In this circuit, all the MOSFETs have the same polarity (i.e. all are N-type MOSFETs in the preferred embodiment). The other leg of reset MOSFET 160 is connected to a leg of MOSFET 140 and a leg of access MOSFET 190. Access MOSFET 190 functions as a cascode transistor to isolate the common node of MOSFETs 190 and 140, from the output node (drain of access MOSFET 190). A row select MOSFET 180 has one leg connected to MOSFET 140 and the other leg connected to columns bus 200. Column bus 200 connects all the pixels in a column of the photodetector array by way of the row select MOSFET 180 to a source supply 300. Row bus 220 connects all the pixel resets in a row to an access supply 400. Tapered reset supply 500 supplies an optimized active-pixel reset waveform (FIG. 2) to the gate of MOSFET 160.

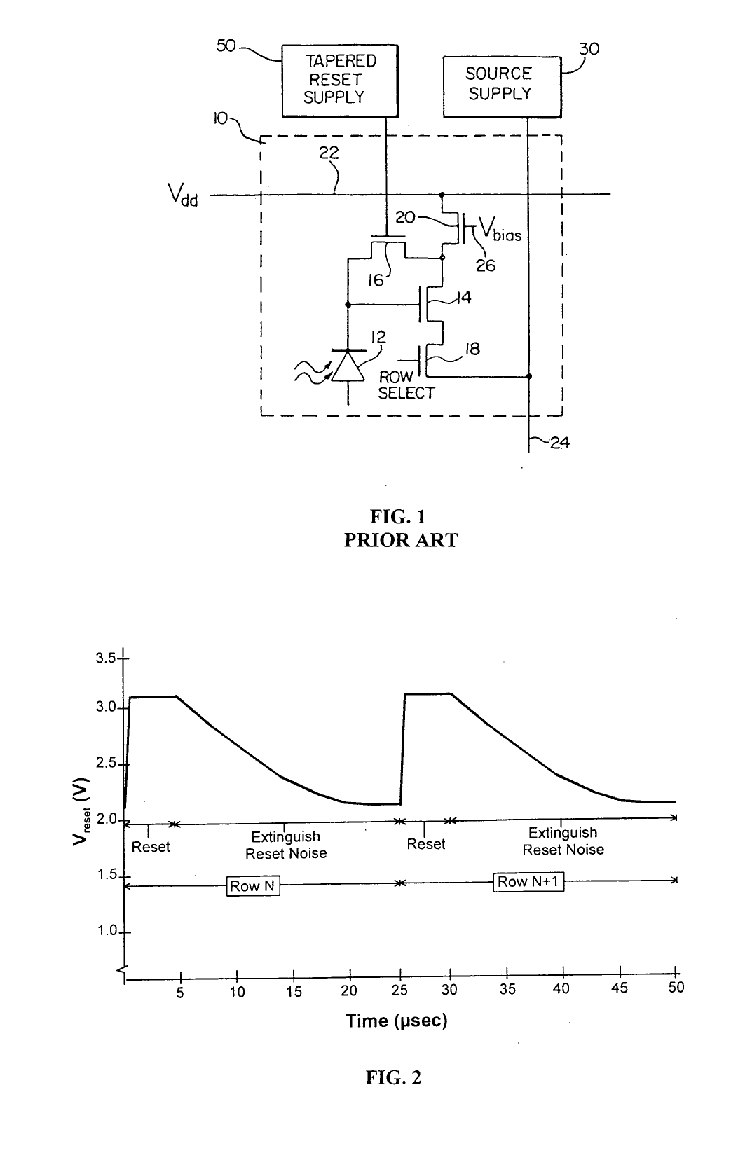

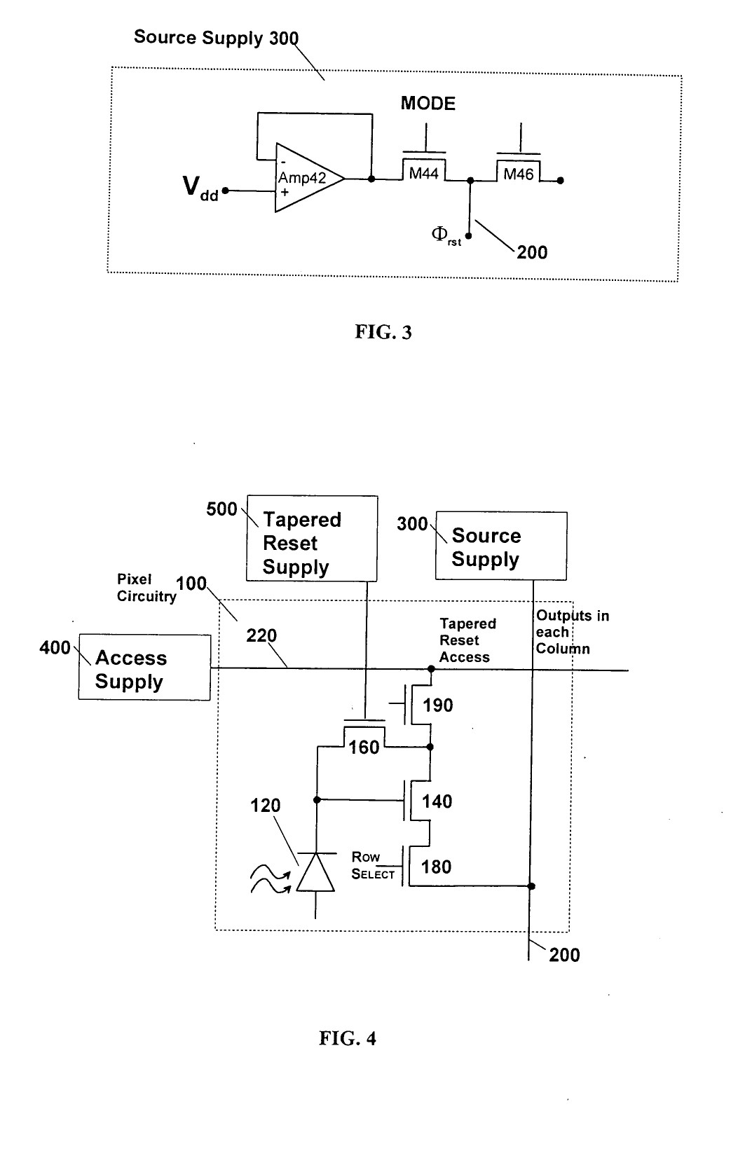

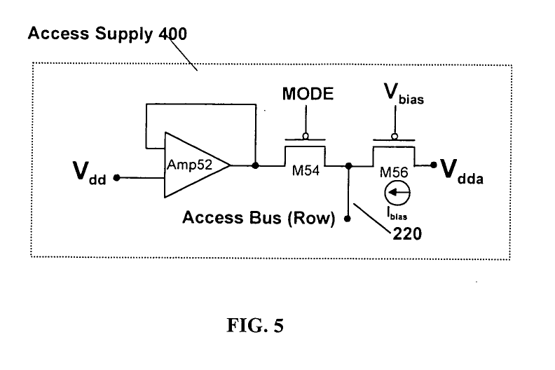

The Access Supply 400 is a current source that comprises a distributed feedback amplifier, when connected to with the pixel MOSFETs. As a result, the feedback amplifier is a cascoded inverter, having gains 100-1000 times greater than the circuit illustrated in FIG. 1. As shown in further detail in FIG. 5, Access Supply 400 may comprise bias transistor M56 and mode transistor M54. Mode transistor M54 is disabled when MODE is set high so that bias transistor M56 forms a distributed cascaded inverting amplifier with the transistors in the pixel. When MODE is set low, V_{dd} sets the pixel transistors to operate as a source follower. The Supply Access 300 may be constructed as shown in FIG. 3, comprising two MOSFETs M44, M46 and an op-amp Amp42.

Photodiode 120 may be a substrate diode, for example, with the silicide cleared. In this embodiment, it is necessary to clear the silicide because it is opaque to visible light. Pixel 100 is designed to obtain the largest available light detecting area while providing broad spectral response, control of blooming and signal integration time, and compatibility with CMOS production processes.

For maximum compatibility with standard submicron CMOS processes, photodiode 120 may be formed at the same time as the lightly doped drain (LDD) implant of n-type MOSFETs for the chosen process; this creates an n-on-p photodiode junction in the p-type substrate. Since no additional ion implantation is necessary, the process and wafer cost for active-pixel circuit 100 are the same as those of standard, high volume digital electronic products.

The application of the tapered reset waveform (FIG. 2) to the amplifier enables the reset noise (kTC noise) envelope to decay before the reset MOSFET 160 is completely opened. The invention also reduces the fixed-pattern offsets from MOSFET 140 in each pixel because the photodiode node charges to a voltage that cancels MOSFET 140 variations from pixel-to-pixel. By using a tapered reset with a cascaded inverter, a row is resettable to within several microseconds for full noise suppression, or a shorter time for less noise reduction.

The column bus 200 is preferably monitored by a standard column buffer, such as disclosed in U.S. Pat. No. 5,892,540, entitled LOW NOISE AMPLIFIER FOR PASSIVE PIXEL CMOS IMAGER, inventors Kozlowski et al., herein incorporated by reference, to read the video signal when it is available. The key requirements on the column buffer are similar to conventional designs having to handle voltage-mode signals and are well known in the art.

The reset clock signal (FIG. 2), for circuit 100, and the clocking of source supply 300 (FIG. 3) which facilitate active-pixel reset and readout, is generated on-chip using standard CMOS digital logic. This digital logic scheme thus enables “windowing,” wherein a user can read out the imager in various formats simply by enabling the appropriate support logic to clock the appropriate sub-format. With windowing, the 1920×1080 format of the prototype embodiment can be read out as one or more arbitrarily sized and positioned M by N arrays without having to read out the entire array. For example, a user might desire to change a computer-compatible “VGA” format (i.e., approximately 640×0.480) to either Common Interface Format (CIF; nominally 352×240) or Quarter Common Interface Format (QCIF; nominally 176×120) without having to read out all the pixels in the entire array. This feature simplifies support electronics to reduce cost and match the needs of the particular communication medium. As an example, a personal teleconference link to a remote user having only QCIF capability could be optimized to provide QCIF resolution and thus reduce bandwidth requirements throughout the teleconference link. As a further example, an imager configured on Common Interface Format (CIF) could provide full-CIF images while supplying windowed information for the portions of the image having the highest interest for signal processing and data compression. During teleconferencing the window around a person's mouth (for example) could be supplied more frequently than the entire CIF image. This scheme would reduce bandwidth requirements throughout the conference link.

A preferred embodiment of the present invention has the approximate design values when incorporated in a pixel having 5 μm by 5 μm real estate in 0.25 μm CMOS process technology:
Mosfet 180: W=0.48 μm and L=0.34 μm
Mosfet 160: W=0.48 μm and L=0.42 μm
Mosfet 140: W=0.6 μm and L=0.50 μm
Mosfet 190: W=0.48 μm and L=0.34 μm
Photodiode 120: C_{det}=4.5 fF

Those skilled in the art will appreciate that various adaptations and modifications of the just described preferred embodiments can be configured without departing from the scope and spirit of the invention. Therefore, it is to be understood that, within the scope of the appended claims, the invention may be practiced other than as specifically described herein.

1. A pixel circuit comprising:
a photodetector connected to a first node;
a dual-driver MOSFET having a gate connected to the first node;
a reset MOSFET having a first leg connected to the first node and a second leg connected to a second node;
an access MOSFET having a first leg connected to a row bus and a second leg connected to the second node;
a row select MOSFET having a first leg connected to the dual-driver MOSFET and a second leg connected to a column bus;
an access supply connected to the row bus;
a source supply connected to the column bus; and
a reset supply connected to a gate of the reset MOSFET;
wherein the MOSFETs all have the same polarity.

2. The pixel circuit of claim 1, wherein the photodetector is a photodiode.

3. The pixel circuit of claim 2, wherein the access supply comprises a current source that is a distributed feedback amplifier when connected to the MOSFETs.

4. The pixel circuit of claim 3, wherein the feedback amplifier is a cascoded inverter.

5. The pixel circuit of claim 4, wherein the reset supply produces a tapered waveform.

6. The pixel circuit of claim 5, wherein the source supply comprises an operational amplifier, a bias transistor and a mode transistor.

7. The pixel circuit of claim 6, wherein the MOSFETs are N-type MOSFETs.

8. An active pixel sensor array having a plurality of pixel sensors, each pixel sensor comprising:
a photodiode connected to a first node;
a dual-driver MOSFET having a gate connected to the first node;
a reset MOSFET having a first leg connected to the first node and a second leg connected to a second node;
an access MOSFET having a first leg connected to a row bus and a second leg connected to the second node;
a row select MOSFET having a first leg connected to the dual-driver MOSFET and a second leg connected to a column bus;
an access supply connected to the row bus, the access supply comprising a distributed feedback amplifier;
a source supply connected to the column bus; and
a reset supply connected to a gate of the reset MOSFET, the reset supply producing a tapered reset waveform;
wherein the MOSFETs all have the same polarity.

9. The pixel array of claim 8, wherein the source supply comprises an operational amplifier, a bias transistor and a mode transistor.

10. The pixel array of claim 9, wherein the MOSFETs are N-type MOSFETs.

11. A CMOS image sensor of the type having a plurality of active pixel sensors arranged in rows and columns and connected to row and column buses, the improvement comprising an access supply connected to a column bus, the access supply comprising a current source configured as a distributed feedback amplifier.
